(19) United States
(12) Patent Application Publication
(10) Pub. No.: US 2014/0326289 A1
(43) Pub. Date: Nov. 6, 2014

(54) PHOTOVOLTAIC CELL ASSEMBLY AND METHOD OF MANUFACTURING SUCH A PHOTOVOLTAIC CELL ASSEMBLY

(71) Applicant: Ian John Bennet, Petten (NL)

(72) Inventor: Ian John Bennet, Petten (NL)

(73) Assignee: STICHTING ENERGIEONDERZOEK CENTRUM NEDERLAND, Petten (NL)

(21) Appl. No.: 14/342,591

(22) PCT Filed: Aug. 31, 2012
(86) PCT No.: PCT/NL2012/050602

§ 371 Date: May 6, 2014

(30) Foreign Application Priority Data
Sep. 2, 2011 (NL) 2007345

(51) Int. Cl. H01L 31/05

(52) U.S. Cl. CPC H01L 31/0508; H01L 31/0512
USPC 136/244; 438/66

(57) ABSTRACT

A method a photovoltaic cell assembly comprising a first and second photovoltaic cell is manufactured using an electrically conducting connection strip having a first and second lip integrally formed in or extending from the connection strip, a width of the first and second lip being smaller than a width of the strip. The lips are preferably bonded to the contact pads on a side of the cell at which the connection strip is located. Ultrasonic bonding of the first and second lip to the contact pads of the first and second photo-voltaic cell respectively.

### FIELD OF THE INVENTION

The invention relates to a photovoltaic cell assembly and a method of manufacturing such a photovoltaic cell assembly.

### BACKGROUND

Known photovoltaic cells are based on a semiconductor substrate, such as Silicon. One surface of the substrate is a photon collecting surface and an opposite second surface of the substrate is the back surface. In a low cost manufacturing process conductor lines and contact pads (collectively referred to as tracks in the following) are printed or screen printed on a surface of the substrate. Typically, the tracks are not printed directly on the bulk of the substrate but on a doped layer or region with a higher doping concentration than the bulk, with the same or opposite polarity as the doping of the bulk. The tracks may be printed on a dielectric layer on such a higher doped layer or region for example. The conducting tracks may be applied by printing a paste of aluminum grains. Subsequently the paste may be sintered in a firing step that electrically and mechanically connects the track to the higher doped layer or region, or to the bulk. This produces tracks of porous material on the substrate, by means of which photocurrent can be extracted from the substrate. US2011/014743 discloses various compositions and processes for manufacturing thick film conductors of this type.

In a solar cell assembly the tracks of different cells have to be connected to each other and to output terminals by an added electric conductor to be able to transport electric current from the semiconductor substrate. Conventionally the conductor is soldered onto the tracks. Soldering forms a strong bond with the porous material, because the soldering material penetrates into the pores, locally strengthening the tracks. However, during soldering of the electric wiring onto the tracks on the substrate, thermal stresses are introduced, which can result in crack initiation in the bond, reducing the lifetime before failure and can also result in crack growth into the semiconductor substrate.

When any of the soldered bonds fail, the overall efficiency of a photovoltaic cell assembly can decrease early in its lifetime, resulting in a low or no output of electricity. As a result the efficiency and lifetime of the photovoltaic cell assembly can be considerably reduced.

US2005/217718 discloses a method of bonding a tab to a photovoltaic cell using flame soldering. The document mentions a list of alternative bonding techniques, including a contact technique like ultrasound welding. An embodiment is shown wherein the tab is provided at the back of the cell and attached to the front of the cell by a lip. In this embodiment, the lip is punched out of the tab and passed to the front through a small opening in the cell, in order to reach the front side from the back side where the tab is located.

### SUMMARY

An object of the invention is therefore to provide a photovoltaic cell assembly and a method of manufacturing such a photovoltaic cell assembly that mitigates at least one of the above mentioned drawbacks.

Thereto, the invention provides a method of manufacturing a photovoltaic cell assembly, comprising a first and second photovoltaic cell, each comprising a semiconductor substrate comprising a contact pad printed thereon; providing connection strip having a first and second lip integrally formed in or extending from the connection strip, a width of the first and second lip being smaller than a width of the strip; and ultrasonic bonding of the first and second lip to the contact pads of the first and second photovoltaic cell respectively.

Ultrasonic bonding is known per se, for example from integrated circuit packaging, where it is used to connect bond wires to solid pads. Ultrasonic bonding may be realized for example by pressing the lip against the contact pad with a vibrating bonding head.

Ultrasonic bonding is a cold bonding technique that does not introduce local thermomechanical stresses. Ultrasonic bonding of lips that are part of a wider connection strip makes it possible to combine a strip of sufficient electric conductivity to carry the power current produced by the photovoltaic cell with little loss during use and at the same time to allow for a contact that not too unwieldy to be amenable to ultrasonic bonding during manufacture. Hence, the limited width is not provided in order to pass the lip through an opening. In an embodiment the lips may be bonded to the contact pads on a side of the cell at which the connection strip is located.

In an embodiment, the strip has a thickness of no more than two tenths of a millimeter, with a width of at least five millimeter and lips with a width of no more than three millimeter. A strip of aluminium foil may be used for example, with the outline of the lips cut out from the strip. With ultrasonic bonding the bond between the contact pad and the lip may be stronger than the material of the strip when the strip is pulled from the cells. A lip may be defined by an outline that divides the lip from the strip. The outline may be internal in the strip. The outline may be U shaped for example.

In an embodiment the semiconductor substrate of a first and second photovoltaic cell may each comprise at least two contact pads printed on the substrate, and the connection strip may have at least two integrally formed lips for each of the photovoltaic cells to be ultrasonically bonded to the at least two contact pads on each photovoltaic cell. Thus a connection to a plurality of printed conductor tracks on the photovoltaic cell may be provided without a need for a bus bar or other interconnection between the tracks printed on the cell.

In an embodiment the width of the lip may be bigger than the width of the contact pad. This may ensure that during bonding of the lip to the contact pad, possible misalignment of the lip with respect to the contact pad need not affect the contact area. In this way most or all of the bonding surface of the contact pad may be used for ultrasonically establishing bond between the lip and the contact pad.

In an embodiment the contact pad material may contain silver grains. The contact pad material may comprise glass frit particles. During sintering of the contact pad material onto the substrate, the glass frit particles may at least partly melt and are able to migrate and/or diffuse through the contact pad material in the direction of the substrate and may partly migrate and/or diffuse into the substrate. This will make the bond between the contact pad and the substrate stronger. The bond between the semiconductor substrate and the contact pad may be stronger than the bond between the contact pad and the lip.

The invention further provides a photovoltaic cell assembly according to the above, comprising: a first and second photovoltaic cell, each comprising a semiconductor substrate comprising a contact pad printed thereon, a connection strip having a first and second lip integrally formed in or extending from the connection strip, a width of the first and second lip being smaller than a width of the strip, wherein the first and second lip are ultrasonically bonded to the contact pads of the first and second photo-voltaic cell respectively.

### BRIEF DESCRIPTION OF THE DRAWING

The invention will further be elucidated on the basis of a description of exemplary embodiments by reference to the drawings. The exemplary embodiments are given by way of non-limitative illustration of the invention. In the drawings:

FIG. 1a, b show a schematic top view of a first and a second embodiment of a photovoltaic assembly according to the invention.

FIG. 2a shows a perspective close-up view of a connection strip with a lip, according to FIGS. 1a, b.

FIG. 2b shows a side view of the connection strip with lip according along line A-A in FIG. 2a.

FIG. 3 shows a side view of photovoltaic cell according to FIG. 1, wherein the lip is ultrasonically bonded to the bonding surface of the contact pad.

FIG. 4 shows a side view of a second embodiment, wherein a conducting track and an insulation layer is applied between the connecting strip and the substrate.

FIG. 5 illustrates pores

### DETAILED DESCRIPTION OF EXEMPLARY EMBODIMENTS

It is noted that the figures are only schematic representations of embodiments of the invention that are given by way of non-limited example.

In the figures, the same or corresponding parts are designated with the same reference numerals.

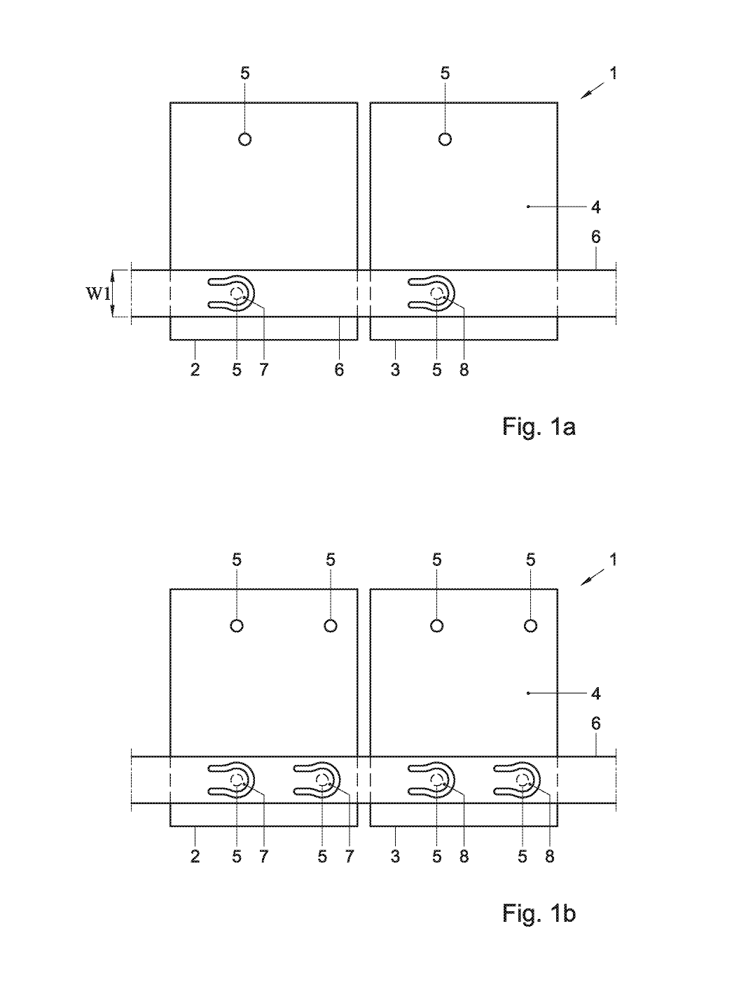

Figure la shows a photovoltaic cell assembly 1 comprising: a first and second photovoltaic cell 2, 3, each comprising a semiconductor substrate 4 with a printed contact pad 5 and an electrically conductive connection strip 6 having a lips 7, 8. FIG. 1b shows a similar photovoltaic cell assembly 1 with a plurality of printed contact pad 5 on each photovoltaic cells and a connection strip 6 with a correspondingly larger number of lips 7, 8. Lips 7, 8 are attached to contact pads 5 of the first and second photo-voltaic cell 2, 3 by ultrasonic bonds, i.e. bonds that need not contain solder material, or more generally other material than that of the contact pads 5 and connection strip 6 itself. During normal use, connection strip 6 is used to conduct current from photovoltaic cells 2, 3.

Contact pads 5 of first and second photovoltaic cell 2, 3 may provide connections to emitter and surface field areas of first and second photovoltaic cell 2, 3 respectively. Although not shown, it should be appreciated that further strips may be provided to connect the photovoltaic cell 2, 3 to other cells (not shown) of the assembly or to external terminals. In an embodiment a plurality of strips may be used in parallel between first and second photovoltaic cell 2, 3.

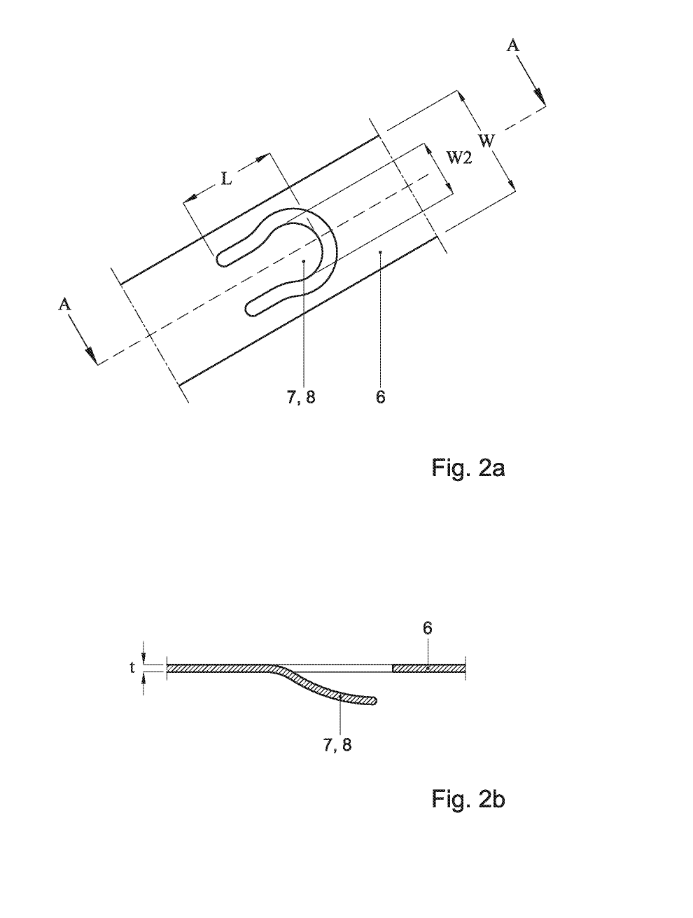

FIGS. 2a, b show a detail of connection strip 6. Connection strip 6 has a width W and lip 7,8 has a width W1 and a length L. The outline of lip 7, 8 may have two parallel sections, extending from the base of the lip, transverse to a virtual baseline of the lip, and a rounded section connecting the parallel sections on the side of the lip away from the baseline.

Typically, the width W of the connecting strip 6 may be between 5-8 mm, preferably between 6-7 mm, for example 6.5 mm. The thickness t of the strip 6 may be between 50-250 um, preferably 80-120 um, for example 100 um. The integrally formed lip may have a width W1 of 1-3 mm, for example 2 mm and may have a length L between 3-6 mm, preferably between 4-5 mm, for example 4.5 mm. The contact pad 5 may have a bonding area between 0.5 mm² and 1.5 mm², for example 1 mm². Preferably, the width W1 of lips 7, 8 is larger than the corresponding width of contact pads 5. This reduces demands on manufacturing tolerances. Preferably, the length of lips 7, 8 is at least as large as the corresponding lengths of contact pads 5.

The strip 6 may be made of a strip of sheet metal. The strip 6 may be formed from an electrically conducting foil. The material of the strip/foil may alternatively comprise copper, aluminum, or any other suitable conducting material for ultrasonic bonding.

Although an example has been shown wherein lips 7, 8 are internal to strip 6 (i.e. with a lip outline bordering on all sides on strip 6), it should be appreciated that alternatively lips 7, 8 on the edge of strip 6 may be used, so that part or all of the lip outline does not border on strip 6. Lips having their baseline along the edge of strip may be used. However, use of a baseline within strip 6 has the advantage that more efficient use is made of the material of strip 6.

The photovoltaic cells 2, 3 each comprise a semiconductor substrate, such as a silicon wafer, each doped to provide a first conductivity type (n type or p type). In or on the substrate an emitter region or regions of a second conductivity type opposite to the first conductivity type is or are provided, with a semi-conductor junction between this (each) region and the substrate or part of the substrate that has the first conductivity type. First printed conductor tracks are provided in electrical contact with this emitter region or these regions. Second printed conductor tracks are provided in electrical contact with the substrate or part of the substrate that has the first conductivity type (usually the second printed conductor tracks are provided in electrical contact with a surface field region or regions with doping of the first conductivity type, with enhanced density compared to the bulk of the semi-conductor substrate). The conductor tracks may comprise sintered grains of aluminium for example. Contact pads 5 are in electrical contact with the first or second printed conductor tracks. Contact pads 5 may comprise sintered grains of silver for example.

In an embodiment the first and second conductor tracks, as well as the contact pads may be provided on the same surface of the photovoltaic cell, which forms the back surface of the cell which is turned away from the sun (or other light source) during use. In this case first and second conductor tracks may be provided interdigitated with one another for example. The semiconductor substrate of the photovoltaic cells may each comprise interdigitated first and second substrate areas of mutually opposite conductivity type, the first and second conductor lines being provided on the first and second substrate areas respectively, so that first and second conductor tracks alternate in the direction transverse to the length of the tracks. Conventionally, the parallel first conductor tracks are mutually laterally connected on one side by a first bus bar and the second conductor tracks between these first conductor tracks are mutually laterally connected on the other side by a second bus bar. When strip 6 is bonded to contact pad on each of the first conductor tracks, no bus bar is needed, because strip 6 forms an electrical connection between the first conductor lines. The same may be done with a further strip for the second conductor lines.

In other types of cell, the first and second conductor tracks may be provided on mutually opposite surfaces respectively. Optionally one or more vias through the semi-conductor substrate may be provided to connect the first or second conductor tracks on one surface to pads on the opposite surface for connection to the strip.

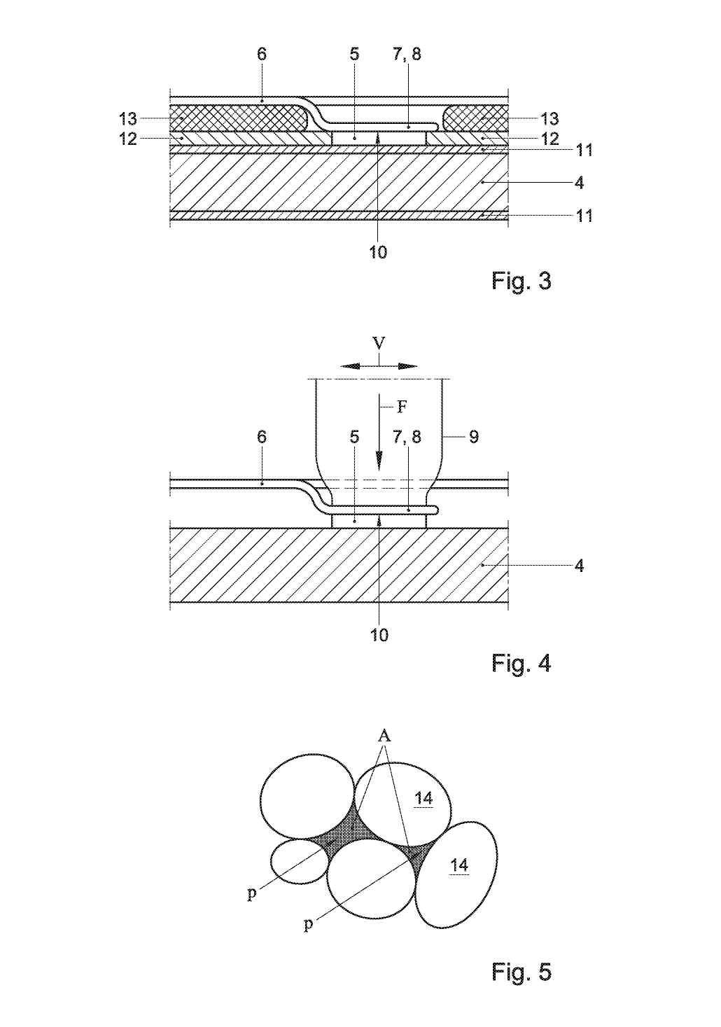

FIG. 3 shows a cross section of a connection between strip 6 and contact pad 5. Semiconductor substrate 4 has a doped emitter or surface field layer 11. A printed track 12 comprising grains of conductor material (e.g. aluminium) is provided on layer 11. Track 12 makes contact with a contact pad 5 comprising grains of conductor material (e.g. silver). It is preferred not to use silver grains for track 12 to reduce costs. Strip 6 is coupled to pad 5 by lip 7, 8 by an ultrasonic bond. Optionally, an insulation layer 13, for example in the form of isolating tape, may be provided between the strip 6 and conducting track 12 and/or the substrate outside the location of pad 5. As can be seen, lips 7, 8 are bonded to contact pad 5 at the side of the photovoltaic cell at which strip 6 is located, preferably the back side. That is, the lips 7, 8 do not pass through the cell. Although an area of the strip that is connected to the strip in all planar directions could be bonded to contact pad 5 when a conventional bonding techniques such as soldering is used, lips 7,8 of limited width compared to the strip are used instead, to facilitate ultrasonic bonding. A lip of limited width ensures that the bond, is not too unwieldy to be amenable to ultrasonic bonding.

In the manufacturing process of photovoltaic cells 2, 3 the tracks and contact pads may be realized by printing a paste containing grains of electric conductor material (e.g. aluminium and/or silver), glass frit and organic components. The organic components are designed to allow the paste to be printed, to allow the paste to be dried so that other printing steps can be performed before firing without damaging the first print and for all organic components to be removed during the firing steps. The paste may also contain additives, for example to improve the adhesion of the metallisation of the paste to the cell after firing.

Typically the paste will be printed indirectly onto the semi-conductor substrate, on a dielectric (electrically isolating) layer on the semi-conductor substrate. Subsequently, the cell is heated to fire the paste. During the firing step at least part of the glass frit and some of the conductor material migrates into the emitter or surface field region, after penetrating the dielectric layer. Also, the material of the grains merges at the contacts between the grains, thus sintering the grains. This results in tracks and contact pads with a porous structure, the pores being formed by the remaining space between the grains.

Known metallization pastes for photo-voltaic cells are designed to make contact with the silicon of the cell. This is achieved by the inclusion of glass frits which etch the surface of the silicon at the peak firing temperature of the paste (between 800 and 900° C.). The organic components generally evaporate during the first phase of firing as the temperature rises to the peak firing temperature. The peak temperature is maintained for a number of seconds. The required time depends on the thickness of the emitter or surface field. The glass must etch far enough to allow contact between the silver and the emitter, but it should not etch through the emitter or surface field. Silver diffuses through the glass forming a spike which contacts the silicon. The conductivity of the fired metallisation is affected by the density of the paste. The width and thickness of the contact points on the cell (several mm in diameter for a circular contact) ensures that there is enough silver to compensate porosity.

Connection strip 6 may be made from a sheet (or foil) of metal copper, aluminum, or any other suitable conducting material for ultrasonic bonding. The outline of lips 7, 8 may be punched out of the sheet (foil) or strip or may be formed by cutting out, e.g. by means of a laser cutting.

FIG. 4 illustrates ultrasonic bonding a bonding head 9 of an ultrasonic bonding apparatus is used to press the lip 7, 8 onto the contact pad 5 with a force F, whilst at the same time the head is made to vibrate in a parallel direction V with respect to the bonding surface 10 of the contact pad 5. Ultrasonic bonding apparatuses are known per se. An ultrasonic bonding apparatus may comprise a vibration driver, a bonding head coupled to the vibration driver and optionally a force actuator coupled to the bonding head. In another embodiment, head 9 of the bonding apparatus may also vibrate in a width direction W1 of the lip 7, 8 or any other direction in the plane parallel to the bonding surface 10 of the contact pad 5.

The pressure force F used to press lip 7, 8 with head 9 onto the bonding surface 10 of the contact pad 5 during bonding may typically be between 5-20 Newton, preferably between 7-18 Newton, for example 8 Newton or 18 Newton. The pressure force F may be applied during 0.2-0.8 seconds, for example 0.5 second. The applied vibration may have frequency between 15-50 kHz, e.g. 36 kHz, with a power between 250-700 Watts, for example 500 Watts. Because only a lip has to be bonded, with an outline that is not in direct connection (other than through the lip) with the strip, the power used for ultrasonic bonding can be kept smaller than when the whole strip would be bonded. At the same time, the grater width of the strip helps keep the resistance of the strip sufficiently low so that power can be obtained efficiently from the photovoltaic cells.

It may be noted that the time for bonding one lip 7, 8 to one contact pad 5 by ultrasonic bonding can be short compared to known other bonding techniques such as soldering. Also, no difficult and time consuming application of soldering material or adhesives is needed.

FIG. 5 illustrates the porous structure of pad 5. Grains 14 leave pores p which show as pore areas A. The porous structure of pad may affect the long reliability of the connection of lip 7, 8 to the pad, and therefore the useful lifetime of the assembly of photovoltaic cells. It has been found that for some pads that may be obtained by printing a paste containing grains of conductor material and subsequent firing strip 6 can be torn off by applying no more than a small pulling force. In contrast with conventional soldering, ultrasonic bonding does not involve filling the pore areas with solder material. When a large fraction of surface of pad 5 consists of open pores, the surface of the pad may easily tear loose. To avoid a need for measures to prevent such small forces, it is desirable to realize bonds that can resist larger forces, e.g. forces at least as large as the forces required to break up connection strip 6.

The pore size and distribution is determined, for example, by making a cross-section through the metallisation, forming an image of the prepared surface followed by image analysis of the image of the prepared surface. The cross-section is made by cutting through the cell and metallisation with a diamond saw followed by embedding the sample in a mounting resin then grinding and polishing of the surface of interest to a 1 micrometer diamond paste finish. Images are made of the prepared surface using either an electron microscope or a light microscope. Pore size and distribution is measured and calculated using image analysis software and the images of the prepared surface. A large area is used to reduce estimation errors in the average pore size and distribution. Alternative methods of pore size measurement include mercury porosimetry. Pore size can be defined from an image by identifying top grains, i.e. grains whose surface is entirely visible without occlusion by other grains, identifying image regions that show surface parts of the top grams, and defining pores as remaining parts of the image between the top grains.

It has been found that contact pads made using a paste with silver grains results in ultrasonic bonds that resist such forces far better than pads made using a paste with aluminium grains.

It has been found that to obtain ultrasonic bonds to silver grain based contact pads that resist such forces, it is necessary to use contact pads 5 with an the average pore area A at the bonding surface 10 of the contact pad 5 of not more that approximately 1.5 um². However, it has also been found that a limitation on the average pore area by itself is not yet sufficient to provide for ultrasonic bonds that resist such forces. In addition a limitation of the distribution of pore area values should be imposed. It has been found that contact pads 5 with an the average pore area of not more that approximately 1.5 um² and that no more than one percent of the pores p at the bonding surface 10 should have a pore area of 10 um² or more.

Experiments have shown that the size and distribution of the pores determine the quality of the ultrasonic bond. Bonds were made on a number of fired silver contacts made with different commercially available metallisation pastes. The bond quality was assessed by performing a peel test. It was found that for a bond between a silver contact on a silicon wafer and an aluminium tab which results in breakage in the aluminium tab, the pore size must be below 1.5 μm² and have less than one percent pores with a size larger than 10 μm². Ultrasonic bonding of an aluminium tab on a silver metallisation with an average pore size of 0.3 μm² and approximately 2000 ppm pores with a size larger than 10 μm² achieved consistently high quality bonds with breakage in the aluminium tab for over 100 contacts made and tested.

Ultrasonic bonds with unfilled pores of such a large size can lead to crack initiation, of cracks that propagate in the surface of contact pad 5. By using pads that have less than 1% of such pore areas on the bonding surface 10, this risk of failure due to the bond during the operational lifetime of the assembly of photovoltaic cells is kept below that of other sources of failure.

Average pore size and the fraction of large pores can be adjusted in many ways. The average pore area and pore area value distribution depends on the distribution of the size and shape of the grains of conductor material (e.g. silver grains) and on processing conditions. The porosity of a fired silver metallisation on a photo-voltaic cell is governed by the size and shape of the silver particles used to make the paste, the nature of the organic components of the paste and the processing of the paste including drying and firing temperature and time. The size and shape of the silver particles will affect the packing density of the particles in the paste before firing with smaller, flatter particles generally resulting in a higher packing density. Silver particles used in metallisation paste typically have dimension in the order of a few μm. A higher packing density will result in a higher density after firing as the contact area between the silver particles will be greater resulting in enhanced diffusion between the particles. A disadvantage of the smaller particles is that they are more difficult to keep in suspension in the silver paste. The smaller particles have a tendency to separate from the organic components of the paste resulting in an inconsistent print quality if the paste is not sufficiently and continuously mixed.

The average pore area is determined by a combination of grain size, and average deviation from spherical shape of the metal grains used to make the metallization paste. Generally a smaller grain size will result in a smaller average pore area. Hence the average pore size may be adjusted by using grains of different size and the fraction of pores with an area above a predetermined area may be adjusted by using grains with a different size distribution (e.g. a grain size distribution that is more narrowly concentrated around the average grain size, in order to reduce the number of pores above the predetermined area). To obtain pads with the desirable average pore area A and limited number of larger pores, the pad surface on a test cell may be inspected under a microscope to determine the values of these quantities. The composition of the paste may be adapted if the values do not satisfy the conditions: pastes with smaller average grain size and/or different average deviation from spherical shape may be tested until the conditions are found to be met.

A paste that is commercially obtainable from Ferro Electronic Materials, South Plainfield, N.J. 07080, USA under the product name Ferro NS181 may be used for example, to realize the required average pore size and fraction of large pores.

The person skilled in the art will appreciate that the contact pad and the conducting track 12 as well as the connecting strip 6 may be connected either to a front and/or back side of the semiconductor substrate 4.

1. A method of manufacturing a photovoltaic cell assembly, comprising a first and second photovoltaic cell, each comprising a semiconductor substrate with a contact pad printed thereon, the method comprising the steps of:
providing an electrically conducting connection strip having a first and second lip integrally formed in or extending from the connection strip, a width of the first and second lip being smaller than a width of the strip;
ultrasonic bonding of the first and second lip to the contact pads of the first and second photo-voltaic cell respectively.

2. A method according to claim 1, wherein the lips are bonded to the contact pads on a side of the cell at which the connection strip is located.

3. A method according to claim 1, wherein the semiconductor substrate of the first and second photovoltaic cell comprise further contact pads printed thereon and the connection strip has further integrally formed lips, the method further comprising ultrasonically bonding the further integrally formed lips to the further contact pads.

4. A method according to claim 3, wherein the semiconductor substrate of the first and second photovoltaic cell each comprise interdigitated first and second conductor lines on substrate areas of mutually opposite conductivity type, the contacts and the further contact pads lying on the first conductor lines, the connection strip forming an electrical connection between the first conductor lines.

5. A method according to claim 1, wherein the first lip is internal to are internal to the strip, the first lip having an outline having two parallel sections, extending from the base of the lip and a rounded section connecting the parallel sections on the side of the lip away from the base of the lip.

6. A method according to claim 1, wherein the first lip is located on an edge of the strip, part or all of an outline of the lip not bordering on the strip.

7. A method according to claim 1, wherein the average pore area at the bonding surface of the contact pad is approximately 1.5 um² and a fraction of pores with a pore area of 10 um² at the bonding surface is less then one percent.

8. A method according to claim 1, wherein the contact pad is applied to the semiconductor substrate by:
printing contact pad material comprising grains of conductor material onto the semiconductor substrate;
sintering the contact pad material on the semiconductor material;
bonding of the contact pad to the sintered contact pad.

9. A method according to any one of the preceding claims, wherein the contact pad material comprises silver grains.

10. A method according to any one of the preceding claims, wherein the connection strip is made of aluminium.

11. A method according to claim 1, wherein the connection strip has a thickness of less than a quarter millimeter.

12. A method according to claim 1, wherein the connection strip has a width of at least five millimeter

13. A method according to claim 1, wherein the connection lips each have width of at most three millimeters.

14. A photovoltaic cell assembly, comprising:
a first and second photovoltaic cell, each comprising a semiconductor substrate comprising a contact pad printed thereon
an electrically conducting connection strip having a first and second lip integrally formed in or extending from the connection strip, a width of the first and second lip being smaller than a width of the strip;
wherein the first and second lip are ultrasonically bonded to the contact pads of the first and second photo-voltaic cell respectively.

15. A photovoltaic cell assembly according to claim 14, wherein the lips are bonded to the contact pads on a side of the photovoltaic cells at which the strip is located.

16. A photovoltaic cell assembly according to claim 14, wherein
the semiconductor substrate of the first and second photovoltaic cell comprise further contact pads;
the connection strip has further integrally formed lips ultrasonically bonded to further contact pads.

17. A photovoltaic cell assembly according to claim 16, wherein the semiconductor substrate of the first and second photovoltaic cell each comprise interdigitated first and second conductor lines on substrate areas of mutually opposite conductivity type, the contacts and the further contact pads lying on the first conductor lines, the connection strip forming an electrical connection between the first conductor lines.

18. A photovoltaic cell assembly according to claim 14, wherein the first lip is internal to are internal to the strip, the first lip having an outline having two parallel sections, extending from the base of the lip and a rounded section connecting the parallel sections on the side of the lip away from the base of the lip.

19. A photovoltaic cell assembly according to claim 14, wherein the first lip is located on an edge of the strip, part or all of an outline of the lip not bordering on the strip.
